(19) United States
(12) Patent Application Publication
(10) Pub. No.: US 2025/0364378 A1
(43) Pub. Date: Nov. 27, 2025

(54) LEADFRAME AND PACKAGE STRUCTURE

(71) Applicant: CHINGIS TECHNOLOGY CORPORATION, Hsinchu City (TW)

(72) Inventor: Cheng-Fu YU, Hsinchu City (TW)

(21) Appl. No.: 18/828,043

(22) Filed: Sep. 9, 2024

(30) Foreign Application Priority Data
May 23, 2024 (TW) 113119056

(51) Int. Cl. H01L 23/495; H01L 23/00; H01L 23/16; H01L 25/065

(52) U.S. Cl. CPC H01L 23/49548; H01L 23/16; H01L 23/49503; H01L 24/48; H01L 25/0657; H01L 2224/48245; H01L 2225/0651; H01L 2924/186

(57) ABSTRACT

A package structure includes a leadframe, at least one semiconductor die and a plastic package material. The leadframe includes a die pad and a plurality of leads, wherein the leads are located on two sides of the leadframe, respectively. The semiconductor die is disposed on the die pad of the leadframe. The plastic package material is disposed on the leadframe. At least one of the leads has a main body portion and an extending portion, the extending portion extends towards a side of the die pad, a thickness of the extending portion is less than a thickness of the main body portion, and the plastic package material entirely covers the extending portion.

### RELATED APPLICATIONS

This application claims priority to Taiwan Application Serial Number 113119056, filed May 23, 2024, which is herein incorporated by reference.

### BACKGROUND

### Technical Field

The present disclosure relates to a leadframe and a package structure. More particularly, the present disclosure relates to a leadframe and a package structure which include a die pad with the cooling function cooperated with routable leads.

### Description of Related Art

In the package structure of the prior art, when the electrodes of the die and the leads, which are configured to bond the wires, are located on different sides, the wires have to be pull to the locations of the aforementioned leads as much as possible to achieve the purpose of electrical connection, but the conditions such as the wire breakage or the wires touching the periphery of the die may be occurred via the excessively long wires. Therefore, a package structure, which has the routable leads, is gradually developed to improve the aforementioned conditions.

However, the package structure, which has the routable leads, usually excludes the die pad so as to fail to achieve the cooling function, so that the poor electric property may be caused to lead the problem of the low reliability. Therefore, a package structure and a leadframe thereof, which have the flexible wiring layout to enhance the electric property and maintain the cooling function, needs to be developed.

### SUMMARY

According to one aspect of the present disclosure, a package structure includes a leadframe, at least one semiconductor die and a plastic package material. The leadframe includes a die pad and a plurality of leads, wherein the leads are located on two sides of the leadframe, respectively. The semiconductor die is disposed on the die pad of the leadframe. The plastic package material is disposed on the leadframe. At least one of the leads has a main body portion and an extending portion, the extending portion extends towards a side of the die pad, a thickness of the extending portion is less than a thickness of the main body portion, and the plastic package material entirely covers the extending portion.

According to one aspect of the present disclosure, a leadframe includes a die pad and a plurality of leads, wherein the leads are located on two sides of the leadframe, respectively. At least one of the leads has a main body portion and an extending portion, the extending portion extends towards a side of the die pad, and a thickness of the extending portion is less than a thickness of the main body portion.

### BRIEF DESCRIPTION OF THE DRAWINGS

FIG. 1 is a schematic view of a package structure according to the 1st example of the present disclosure.

FIG. 2 is a cross-sectional view of the package structure according to the 1st example in FIG. 1.

FIG. 3 is a schematic view of a package structure according to the 2nd example of the present disclosure.

FIG. 4 is a cross-sectional view of the package structure according to the 2nd example in FIG. 3.

FIG. 5 is a schematic view of a package structure according to the 3rd example of the present disclosure.

FIG. 6 is a cross-sectional view of the package structure according to the 3rd example in FIG. 5.

FIG. 7 is a schematic view of a package structure according to the 4th example of the present disclosure.

FIG. 8 is a cross-sectional view of the package structure according to the 4th example in FIG. 7.

FIG. 9 is a schematic view of a package structure according to the 5th example of the present disclosure.

FIG. 10 is a cross-sectional view of the package structure according to the 5th example in FIG. 9.

FIG. 11 is a schematic view of a package structure according to the 6th example of the present disclosure.

FIG. 12 is a top view of the package structure according to the 6th example in FIG. 11.

FIG. 13 is a cross-sectional view of the package structure according to the 6th example in FIG. 12.

FIG. 14 is another cross-sectional view of the package structure according to the 6th example in FIG. 12.

### DETAILED DESCRIPTION

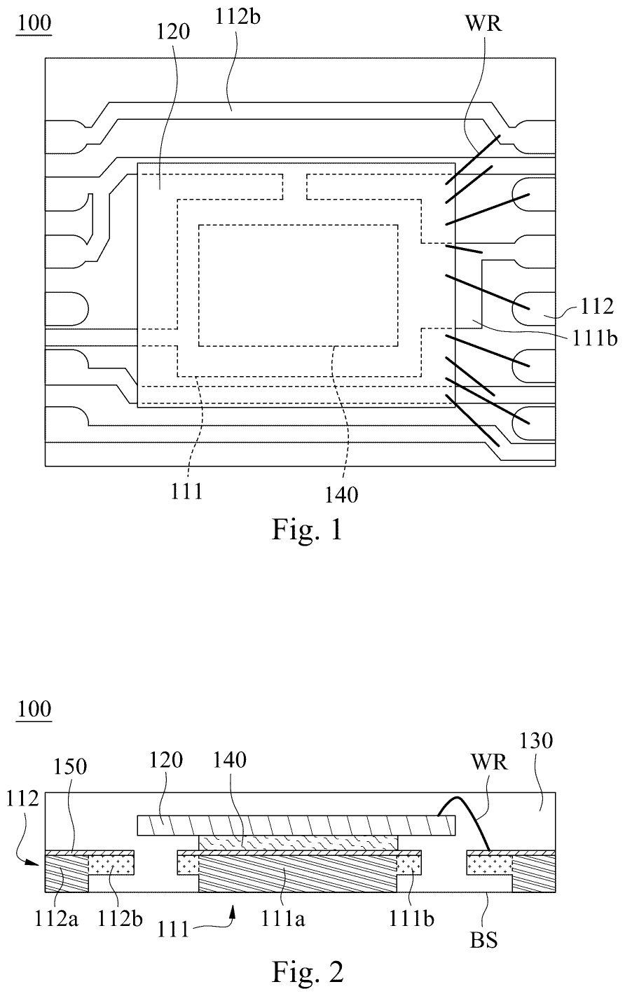

FIG. 1 is a schematic view of a package structure 100 according to the 1 st example of the present disclosure. FIG. 2 is a cross-sectional view of the package structure 100 according to the 1st example in FIG. 1. In FIGS. 1 and 2, the package structure 100 includes a leadframe (its reference numeral is omitted), a semiconductor die 120 and a plastic package material 130. The leadframe includes a die pad 111 and a plurality of leads 112, wherein the leads 112 are located on two sides of the leadframe, respectively, the semiconductor die 120 is disposed on the die pad 111 of the leadframe, and the plastic package material 130 is disposed on the leadframe.

In FIG. 2, at least one of the leads 112 has a main body portion 112a and an extending portion 112b, the extending portion 112b extends towards a side of the die pad 111, and the extending portion 112b can further extend towards a periphery of the leadframe. Therefore, by extending the extending portion 112b of the lead 112 towards a side of the die pad 111, a wire WR can be directly disposed on the lead 112, which the wire WR is predeterminedly disposed on, rather than pulling the wire WR too long. In particular, the lead 112 on a left side in FIG. 1 extends towards a pad (not shown) on a right side of the semiconductor die 120 via the extending portion 112b, so that the wire WR can be avoided to be excessively long to prevent from the problems such as the wire sweep and the wire touching the periphery of the semiconductor die, and hence the cost of the wire bonding can be reduced.

The wiring of the wire WR can be flexibly adjusted via the extending portion 112b, the wire WR can be not limited to the locations of the leads 112, and the electrical property can be flexibly adjusted, such as resistance, inductance and capacitance. Further, the die pad 111 has the cooling function so as to maintain the superior thermal conductivity, so that the reliability of the package structure 100 can be enhanced.

Moreover, a thickness of the extending portion 112b is less than a thickness of the main body portion 112a, and the plastic package material 130 entirely covers the extending portion 112b, wherein the thickness of the extending portion 112b can be half of the thickness of the main body portion 112a. Therefore, the electrical property can be flexibly adjusted under the condition of maintaining the original package outline drawing (POD), and the different POD is not required under the different electrical property. Further, the package structure 100 can be applied to the package type of leaded package, and the package structure 100 can also be applied to the package type of leadless leadframe package (LLP).

The die pad 111 can have a main body portion 111a and at least one extending portion 111b, a thickness of the extending portion 111b can be half of a thickness of the main body portion 111a, the plastic package material 130 entirely covers the extending portion 111b, and the extending portion 111b of the die pad 111 extends towards a periphery of the leadframe. Therefore, the original POD can be maintained under the different electrical properties. Moreover, the disposition structure of the electrical connection between the extending portion 111b of the die pad 111 and the extending portion 112b of the lead 112 can be further obtained under the requirement. It should be mentioned that a portion of each of the die pad 111 and the leads 112 close to a lower surface BS of the package structure 100 can be etched to remove so as to obtain the extending portions 111b, 112b.

Each of at least two of the leads 112 has the main body portion 112a and the extending portion 112b, and the extending portion 112b of one of the at least two of the leads 112 can be electronically connected to the extending portion 112b of the other one of the at least two of the leads 112. Furthermore, each of a plurality of the leads 112 can have the main body portion 112a and the extending portion 112b, and the extending portion 112b of the lead 112 can be electrically connected to the extending portion 112b of another one of the lead 112 or the extending portion 111b of the die pad 111 according to the different electrical requirements.

The package structure 100 can further include a spacer layer 140 disposed between the semiconductor die 120 and the die pad 111. Therefore, the semiconductor die 120, which has the larger area than the die pad 111, can be disposed on the die pad 111 via the spacer layer 140, so that the semiconductor die 120 is not limited to the area of the die pad 111, and the spacer layer 140 can have the buffering function.

The leadframe can further include a coating layer 150 disposed on a continuous surface of the main body portion 112a and the extending portion 112b of the at least one of the leads 112. Moreover, the coating layer 150 is disposed on a surface of each of the leads 112 and a surface of the die pad 111, and the coating layer 150 is disposed on a continuous surface of the main body portion 111a and the extending portion 111b of the die pad 111 and a continuous surface of the main body portion 112a and the extending portion 112b of each of the leads 112. In particular, the coating layer 150 can be a surface, which is plated via silver or gold-nickel-palladium, treated via the surface treatment, but the present disclosure is not limited thereto.

Table 1 lists the values of the electric properties of the package structure 100 according to the 1st example of the present disclosure and the values of electric properties of the package structure according to the comparative example of the prior art, wherein VCC is the leads for power supply, VSS is the ground leads, R is the resistance value, Ls is the inductance value of the self-inductance, and Lm is the inductance value of the mutual inductance. Further, a number of the solder balls of VCC is eight, and a number of the solder balls of VSS is four.

TABLE 1

| | | | |
|---|---|---|---|
| R | Ls | Lm | Ls + Lm |
| (mohm) | (nH) | (nH) | (nH) |

the 1st example-type I

| | | | | |
|---|---|---|---|---|
| VCC | 112.11 | 0.857 | 0.270 | 1.127 |
| VSS | 110.28 | 2.873 | 0.893 | 3.766 |

the 1st example-type II

| | | | | |
|---|---|---|---|---|
| VCC | 268.57 | 1.516 | 0.484 | 2.000 |
| VSS | 164.37 | 3.298 | 0.815 | 4.113 |

the 1st example-type III

| | | | | |
|---|---|---|---|---|
| VCC | 272.91 | 1.510 | 0.543 | 2.053 |
| VSS | 139.46 | 3.003 | 0.924 | 3.927 |

the comparative example

| | | | | |
|---|---|---|---|---|
| VCC | 151.24 | 1.374 | 0.373 | 1.747 |
| VSS | 248.56 | 3.241 | 1.026 | 4.267 |

In detail, according to the comparative example, a wire diameter of each of the wires of the package structure in Table 1 is 25 um, a wire-pulling number of VCC is two, and a wire-pulling number of VSS is three. A wire diameter of each of the wires of the package structure 100 according to the types I, II and III of the 1st example in Table 1 is 18 um. According to the type I of the 1st example, a wire-pulling number of VCC is four, and a wire-pulling number of VSS is five. According to the type II of the 1st example, a wire-pulling number of VCC is two, and a wire-pulling number of VSS is three. According to the type III of the 1st example, a wire-pulling number of VCC is two, and a wire-pulling number of VSS is five. Comparing with the types I, II and III of the 1st example of the present disclosure and the comparative example, the wires with the narrower wire diameter can be applied to the package structure 100 according to the 1st example so as to reduce the package cost, and the number and the length of each of the wires of the package structure 100 according to the 1 st example can be flexibly adjusted according to the requirements of the electric property, so that the better electric property can be obtained, wherein the better electric property is the lower resistance and the lower inductance. It should be mentioned that when the wire diameter of each of the wires is smaller, the resistance is higher so as to easily cause the worse electric property.

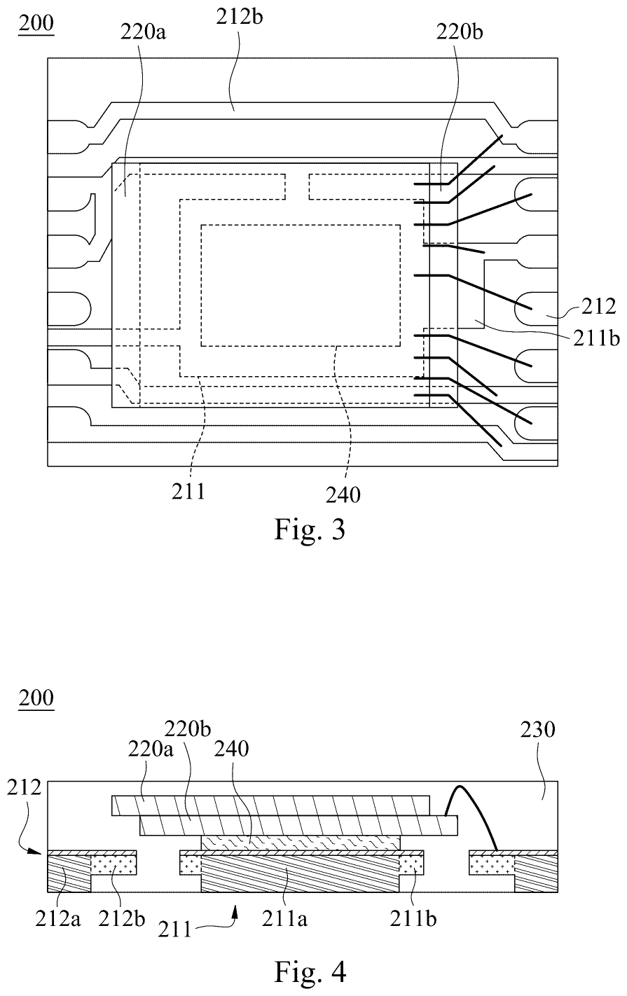

FIG. 3 is a schematic view of a package structure 200 according to the 2nd example of the present disclosure. FIG. 4 is a cross-sectional view of the package structure 200 according to the 2nd example in FIG. 3. In FIGS. 3 and 4, the package structure 200 includes a leadframe (its reference numeral is omitted), two semiconductor dies 220a, 220b and a plastic package material 230. The leadframe includes a die pad 211 and a plurality of leads 212, wherein the leads 212 are located on two sides of the leadframe, respectively, the semiconductor dies 220a, 220b are disposed on the die pad 211 of the leadframe, and the plastic package material 230 is disposed on the leadframe.

In FIG. 4, at least one of the leads 212 has a main body portion 212a and an extending portion 212b, the extending portion 212b extends towards a side of the die pad 211, and the extending portion 212b can further extend towards a periphery of the leadframe.

Moreover, a thickness of the extending portion 212b is less than a thickness of the main body portion 212a, and the plastic package material 230 entirely covers the extending portion 212b, wherein the thickness of the extending portion 212b can be half of the thickness of the main body portion 212a.

The die pad 211 can have a main body portion 211a and at least one extending portion 211b, a thickness of the extending portion 211b can be half of a thickness of the main body portion 211a, the plastic package material 230 entirely covers the extending portion 211b, and the extending portion 211b of the die pad 211 extends towards a periphery of the leadframe.

The package structure 200 can further include a spacer layer 240 disposed between the semiconductor die 220b and the die pad 211, and the semiconductor die 220b is disposed between the semiconductor die 220a and the spacer layer 240.

Moreover, the POD according to the 1st example can be directly applied to the package structure 200 according to the 2nd example via the extending portions 211b, 212b and the spacer layer 240, so that the redrawing cost of the POD can be reduced.

Further, all of other structures and dispositions according to the 2nd example are the same as the structures and the dispositions according to the 1 st example, and will not be described again herein.

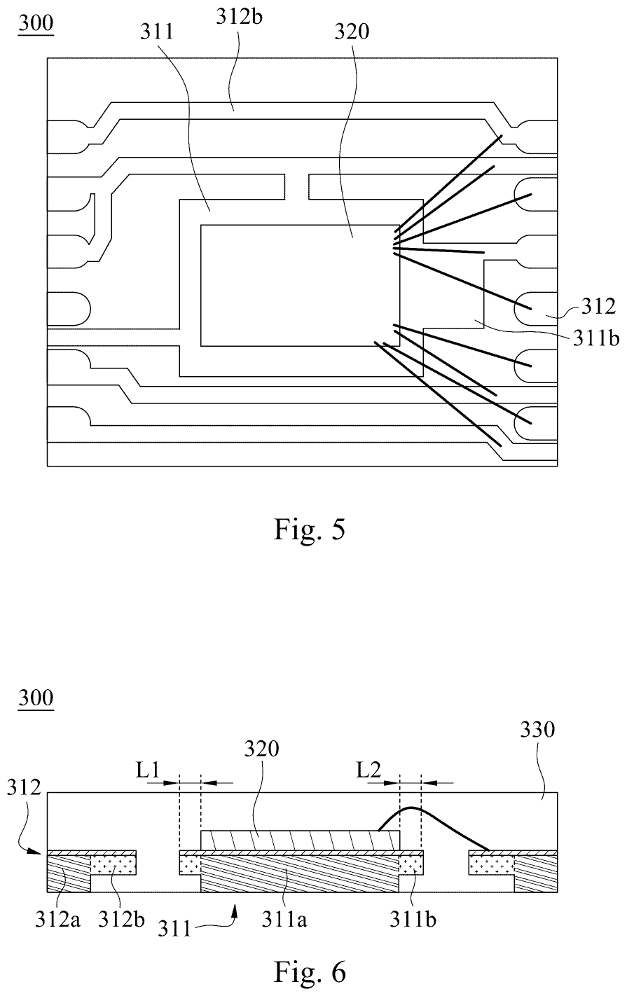

FIG. 5 is a schematic view of a package structure 300 according to the 3rd example of the present disclosure. FIG. 6 is a cross-sectional view of the package structure 300 according to the 3rd example in FIG. 5. In FIGS. 5 and 6, the package structure 300 includes a leadframe (its reference numeral is omitted), a semiconductor die 320 and a plastic package material 330. The leadframe includes a die pad 311 and a plurality of leads 312, wherein the leads 312 are located on two sides of the leadframe, respectively, the semiconductor die 320 is disposed on the die pad 311 of the leadframe, and the plastic package material 330 is disposed on the leadframe.

In FIG. 6, at least one of the leads 312 has a main body portion 312a and an extending portion 312b, the extending portion 312b extends towards a side of the die pad 311, and the extending portion 312b can further extend towards a periphery of the leadframe.

Moreover, a thickness of the extending portion 312b is less than a thickness of the main body portion 312a, and the plastic package material 330 entirely covers the extending portion 312b, wherein the thickness of the extending portion 312b can be half of the thickness of the main body portion 312a.

The die pad 311 can have a main body portion 311a and at least one extending portion 311b, a thickness of the extending portion 311b can be half of a thickness of the main body portion 311a, the plastic package material 330 entirely covers the extending portion 311b, and the extending portion 311b of the die pad 311 extends towards a periphery of the leadframe.

An area of the semiconductor die 320 can be less than an area of the die pad 311, lengths of the extending portions 311b located on two sides of the die pad 311 are L1 and L2, and the length L1 of the extending portion 311b and the length L2 of the extending portion 311b can be the same.

Further, all of other structures and dispositions according to the 3rd example are the same as the structures and the dispositions according to the 1 st example, and will not be described again herein.

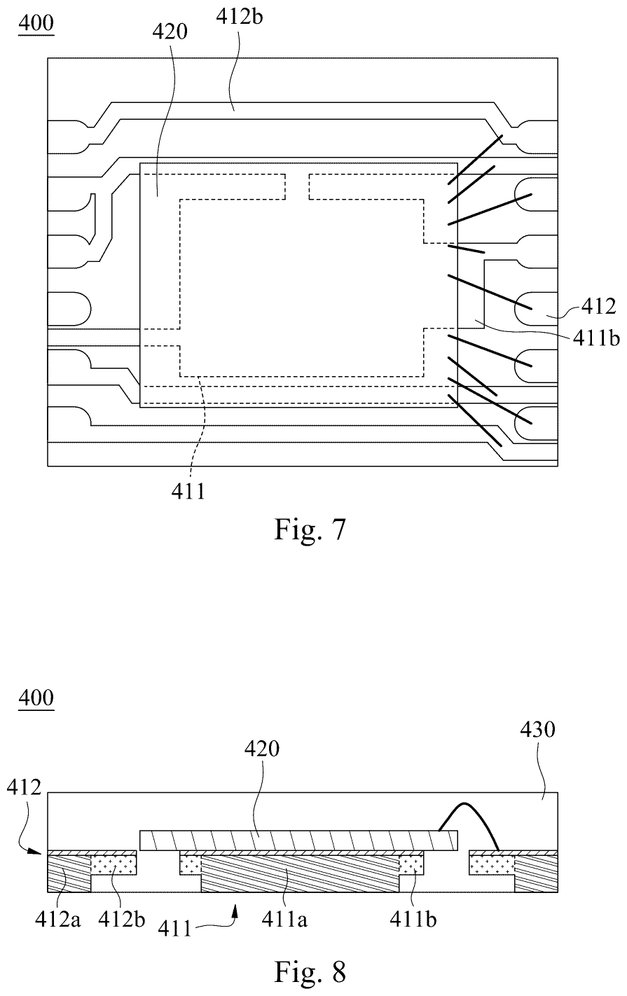

FIG. 7 is a schematic view of a package structure 400 according to the 4th example of the present disclosure. FIG. 8 is a cross-sectional view of the package structure 400 according to the 4th example in FIG. 7. In FIGS. 7 and 8, the package structure 400 includes a leadframe (its reference numeral is omitted), a semiconductor die 420 and a plastic package material 430. The leadframe includes a die pad 411 and a plurality of leads 412, wherein the leads 412 are located on two sides of the leadframe, respectively, the semiconductor die 420 is disposed on the die pad 411 of the leadframe, and the plastic package material 430 is disposed on the leadframe.

In FIG. 8, at least one of the leads 412 has a main body portion 412a and an extending portion 412b, the extending portion 412b extends towards a side of the die pad 411, and the extending portion 412b can further extend towards a periphery of the leadframe.

Moreover, a thickness of the extending portion 412b is less than a thickness of the main body portion 412a, and the plastic package material 430 entirely covers the extending portion 412b, wherein the thickness of the extending portion 412b can be half of the thickness of the main body portion 412a.

The die pad 411 can have a main body portion 411a and at least one extending portion 411b, a thickness of the extending portion 411b can be half of a thickness of the main body portion 411a, the plastic package material 430 entirely covers the extending portion 411b, and the extending portion 411b of the die pad 411 extends towards a periphery of the leadframe. Further, an area of the semiconductor die 420 can be larger than an area of the die pad 411.

Further, all of other structures and dispositions according to the 4th example are the same as the structures and the dispositions according to the 1 st example, and will not be described again herein.

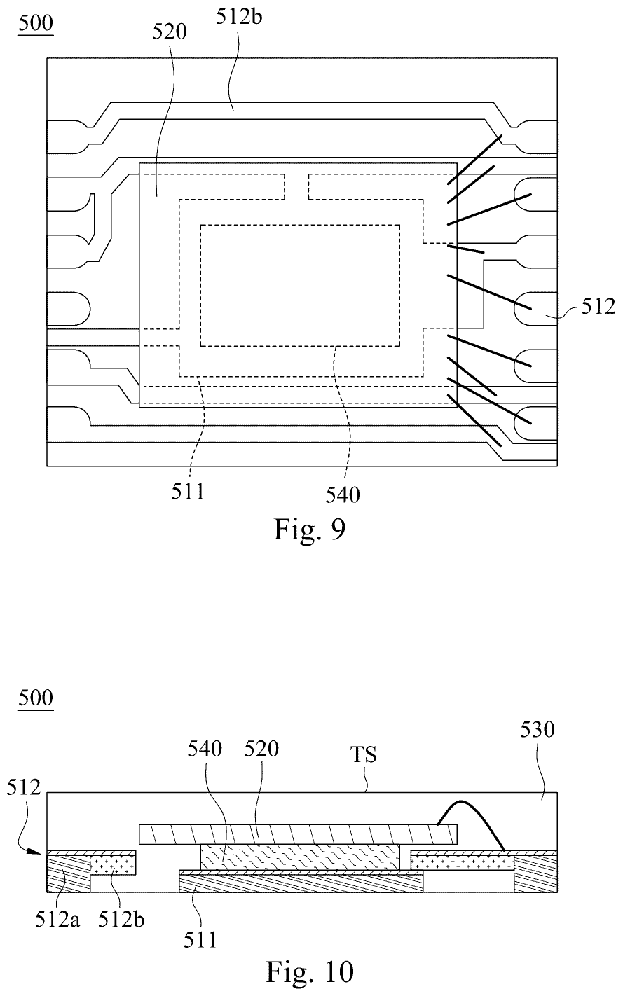

FIG. 9 is a schematic view of a package structure 500 according to the 5th example of the present disclosure. FIG. 10 is a cross-sectional view of the package structure 500 according to the 5th example in FIG. 9. In FIGS. 9 and 10, the package structure 500 includes a leadframe (its reference numeral is omitted), a semiconductor die 520 and a plastic package material 530. The leadframe includes a die pad 511 and a plurality of leads 512, wherein the leads 512 are located on two sides of the leadframe, respectively, the semiconductor die 520 is disposed on the die pad 511 of the leadframe, and the plastic package material 530 is disposed on the leadframe.

In FIG. 10, at least one of the leads 512 has a main body portion 512a and an extending portion 512b, the extending portion 512b extends towards a side of the die pad 511, and the extending portion 512b can further extend towards a periphery of the leadframe. Further, the extending portion 512b can further extend towards the die pad 511, and the extending portion 512b can be electrically connected to the die pad 511.

Moreover, a thickness of the extending portion 512b is less than a thickness of the main body portion 512a, and the plastic package material 530 entirely covers the extending portion 512b, wherein the thickness of the extending portion 512b can be half of the thickness of the main body portion 512a.

The package structure 500 can further include a spacer layer 540 disposed between the semiconductor die 520 and the die pad 511.

In FIG. 10, a central portion of the die pad 511, which is close to an upper surface TS of the package structure 500, can be partially removed by etching, so that a total thickness of the semiconductor die 520 and the spacer layer 540 can be lowered. Therefore, the package structure 500 can be applied to the thinner thickness of the package structure.

Further, all of other structures and dispositions according to the 5th example are the same as the structures and the dispositions according to the 1 st example, and will not be described again herein.

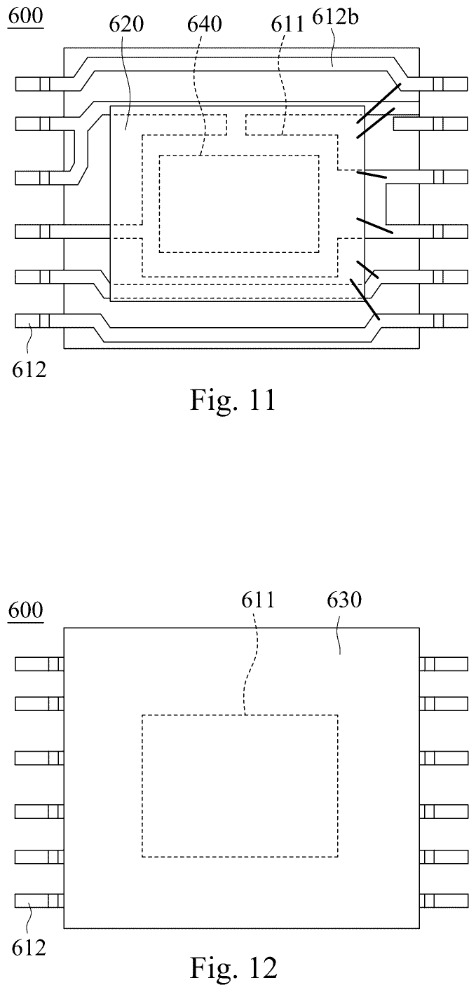

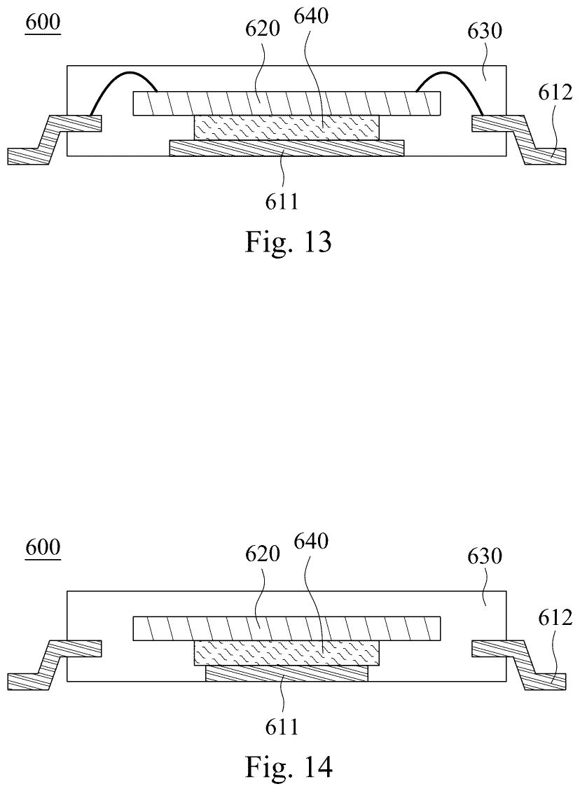

FIG. 11 is a schematic view of a package structure 600 according to the 6th example of the present disclosure. FIG. 12 is a top view of the package structure 600 according to the 6th example in FIG. 11. FIG. 13 is a cross-sectional view of the package structure 600 according to the 6th example in FIG. 12. In FIGS. 11 to 13, the package structure 600 includes a leadframe (its reference numeral is omitted), a semiconductor die 620 and a plastic package material 630. The leadframe includes a die pad 611 and a plurality of leads 612, wherein the leads 612 are located on two sides of the leadframe, respectively, the semiconductor die 620 is disposed on the die pad 611 of the leadframe, and the plastic package material 630 is disposed on the leadframe.

In FIG. 13, at least one of the leads 612 has a main body portion (its reference numeral is omitted) and an extending portion 612b, the extending portion 612b extends towards a side of the die pad 611, and the extending portion 612b can further extend towards a periphery of the leadframe.

Moreover, a thickness of the extending portion 612b is less than a thickness of the main body portion, and the plastic package material 630 entirely covers the extending portion 612b.

The package structure 600 can further include a spacer layer 640 disposed between the semiconductor die 620 and the die pad 611, and an area of the spacer layer 640 can be less than an area of the semiconductor die 620 and an area of the die pad 611.

In particular, the extending portion 612b can be applied to the package structure 600, which the leads 612 protrude towards the plastic package material 630.

FIG. 14 is another cross-sectional view of the package structure 600 according to the 6th example in FIG. 12. In FIG. 14, an area of the spacer layer 640 can be larger than an area of the die pad 611.

Further, all of other structures and dispositions according to the 6th example are the same as the structures and the dispositions according to the 1 st example and the 5th example, and will not be described again herein.

In summary, the wires are not required to pull too long to dispose on the predetermined leads via the extending portions, so that the wires can be avoided to be excessively long to prevent from the problems such as the wire sweep and the wire touching the periphery of the semiconductor die, and hence the cost of the wire bonding can be reduced. Moreover, the wiring of the wires can be flexibly adjusted via the extending portions, the wires can be not limited to the locations of the leads, and the electrical property can be flexibly adjusted, such as resistance, inductance and capacitance. Further, the package structure includes the die pad with the cooling function so as to maintain the superior thermal conductivity, so that the reliability of the package structure can be enhanced. Furthermore, the plastic package material entirely covers the extending portions, so that the original POD can be maintained, the different POD is not required under the different electrical property, and the manufacturing cost can be further lowered.

The foregoing description, for purpose of explanation, has been described with reference to specific examples. It is to be noted that Tables show different data of the different examples; however, the data of the different examples are obtained from experiments. The examples were chosen and described in order to best explain the principles of the disclosure and its practical applications, to thereby enable others skilled in the art to best utilize the disclosure and various examples with various modifications as are suited to the particular use contemplated. The examples depicted above and the appended drawings are exemplary and are not intended to be exhaustive or to limit the scope of the present disclosure to the precise forms disclosed. Many modifications and variations are possible in view of the above teachings.

What is claimed is:

1. A package structure, comprising:
a leadframe, comprising:
a die pad; and
a plurality of leads located on two sides of the leadframe, respectively;
at least one semiconductor die disposed on the die pad of the leadframe; and
a plastic package material disposed on the leadframe;
wherein at least one of the leads has a main body portion and an extending portion, the extending portion extends towards a side of the die pad, a thickness of the extending portion is less than a thickness of the main body portion, and the plastic package material entirely covers the extending portion.

2. The package structure of claim 1, wherein the thickness of the extending portion is half of the thickness of the main body portion.

3. The package structure of claim 1, wherein the extending portion extends towards a periphery of the leadframe.

4. The package structure of claim 1, wherein the die pad has a main body portion and at least one extending portion, a thickness of the at least one extending portion is half of a thickness of the main body portion, and the plastic package material entirely covers the at least one extending portion.

5. The package structure of claim 4, wherein the at least one extending portion of the die pad is electronically connected to the extending portion of the at least one of the leads.

6. The package structure of claim 4, wherein the at least one extending portion of the die pad extends towards a periphery of the leadframe.

7. The package structure of claim 1, wherein each of at least two of the leads has the main body portion and the extending portion, and the extending portion of one of the at least two of the leads is electronically connected to the extending portion of the other one of the at least two of the leads.

8. The package structure of claim 1, further comprising:
a spacer layer disposed between the at least one semiconductor die and the die pad.

9. The package structure of claim 8, wherein a number of the at least one semiconductor die is two, and one of the two semiconductor dies is disposed between the other one of the two semiconductor dies and the spacer layer.

10. The package structure of claim 8, wherein an area of the spacer layer is less than an area of the at least one semiconductor die and an area of the die pad.

11. The package structure of claim 8, wherein an area of the spacer layer is larger than an area of the die pad.

12. The package structure of claim 1, wherein the leadframe further comprises a coating layer disposed on a continuous surface of the main body portion and the extending portion of the at least one of the leads.

13. A leadframe, comprising:
a die pad; and
a plurality of leads located on two sides of the leadframe, respectively;
wherein at least one of the leads has a main body portion and an extending portion, the extending portion extends towards a side of the die pad, and a thickness of the extending portion is less than a thickness of the main body portion.

14. The leadframe of claim 13, wherein the thickness of the extending portion is half of the thickness of the main body portion.

15. The leadframe of claim 13, wherein the extending portion extends towards a periphery of the leadframe.

16. The leadframe of claim 13, wherein the die pad has a main body portion and at least one extending portion, and a thickness of the at least one extending portion is half of a thickness of the main body portion.

17. The leadframe of claim 16, wherein the at least one extending portion of the die pad is electronically connected to the extending portion of the at least one of the leads.

18. The leadframe of claim 16, wherein the at least one extending portion of the die pad extends towards a periphery of the leadframe.

19. The leadframe of claim 13, wherein each of at least two of the leads has the main body portion and the extending portion, and the extending portion of one of the at least two of the leads is electronically connected to the extending portion of the other one of the at least two of the leads.

20. The leadframe of claim 13, further comprising:
a coating layer disposed on a continuous surface of the main body portion and the extending portion of the at least one of the leads.
